(19) United States
(12) Patent Application Publication
(10) Pub. No.: US 2013/0076269 A1
(43) Pub. Date: Mar. 28, 2013

(54) RAIL LIGHT

(71) Applicant: Albert R. Shilton, Pacific Palisades, CA (US)

(72) Inventor: Albert R. Shilton, Pacific Palisades, CA (US)

(21) Appl. No.: 13/623,057

(22) Filed: Sep. 19, 2012

Related U.S. Application Data
(60) Provisional application No. 61/536,307, filed on Sep. 19, 2011.

(51) Int. Cl. F21L 4/08; H05B 37/02; H05K 13/00; F21L 4/00

(52) U.S. Cl. CPC F21L 4/08; F21L 4/00; H05B 37/02; H05K 13/0023
USPC 315/360; 362/183; 362/191; 315/362; 29/825

(57) ABSTRACT

A portable lighting unit is provided which is configured to attach to cables, railing, tubing or any other fixture. In one embodiment, the lighting unit comprises a first housing comprising a first pair of opposing notches, a second housing comprising a second pair of opposing notches, the first and second housings being attachable together with the notches cooperating to receive the fixture through the notches, a photovoltaic cell mounted to one of the first and second housings, a light source mounted to one of the first and second housings, and at least one rechargeable battery housed within one of the first and second housings, the at least one rechargeable battery electrically coupled to the photovoltaic cell and to the light source.

### CROSS-REFERENCE TO RELATED APPLICATION(S)

This application claims priority to and the benefit of U.S. Provisional Application No. 61/536,307, filed Sep. 19, 2011, the entire contents of which are incorporated herein by reference.

### FIELD OF THE INVENTION

The present invention relates to lighting products, and more particularly to a lighting unit for a rail or cable and a method of attaching a lighting unit to a rail or cable.

### BACKGROUND

Various lamp assemblies are available for providing additional or supplemental lighting in desired areas. LED lamps with batteries that are charged by solar cells are found in home and garden applications where electrical outlets are not readily available. The most prevalent use is low level lighting in gardens, parkways and driveways. LED lamps may also be provided on automobiles, trucks, boats, aircraft, and recreational equipment, powered by batteries that are charged by alternators or generators driven by gas or diesel engines. These lamps are typically mounted directly into the structure of the vehicle and hard-wired to the power source.

It may be desired to provide additional lighting on a boat in more remote areas, such as boat railing. Many types of boats and marine vessels include railing at various locations around the perimeter of the boat, such as along walkways, seating areas, and the bow. These areas of the boat may lack suitable lighting for operating the boat after dark, and thus additional lamps may be needed. However, there is some difficulty in attaching a lamp at various locations on a boat, providing power to the lamp, and avoiding interference with other components of the boat. Thus there is still a need for a portable light source that is easily and safely attachable to a variety of rails, bars, and cables, for example, on a boat.

### SUMMARY

An objective of the present invention is to provide illumination apparatus, devices and methods of attaching lights to cable or tubing and the like. Another objective of the present invention is to provide illumination apparatus, devices and methods of attaching lights to cable or tubing and the like, that requires no external electrical power supply or wiring to use. Another objective of the present invention is to provide alternative energy source wherein the batteries are charged by the electromagnetic field created by the electricity being transmitted through the cable (induction).

Another objective of the present invention is to provide illumination apparatus, devices, and methods of attaching lights to cable or tubing and the like, where the apparatus or devices can be permanently or temporarily attached to tubing or cables at any point along the tubing or cable without the need to cut or disconnect the tubing or cable from the supporting structure. Another objective of the present invention is to provide illumination apparatus, devices and methods of attaching lights to cable or tubing and the like, that can be attached easily to straight or curved tubing of varying diameters.

Another objective of the present invention is to provide illumination apparatus, devices and methods of attaching lights to cable or tubing and the like, where the lamps can be adjustably aimed, and/or can be changed or replaced with different color lamps, particularly lamps that will not interfere with night vision, and/or can be automatically switched on at dusk and off at sunrise, and/or can be remotely turned off and on or manually turned off and on with a water proof switch.

Another objective of the present invention is to provide illumination apparatus, devices, and methods of attaching lights to cable or tubing and the like, where the illumination apparatus has modular components that are waterproof when exposed to water, particularly salt water and all types of inclement weather for extended periods of time.

Another objective of the present invention is to provide illumination apparatus, devices and methods of attaching lights to cable or tubing and the like that has an external shape and components that will not interfere with lines, ropes, sails and alike that are likely to come into direct contact with the illumination apparatus during normal use and operation of the boat. The illumination apparatus, devices, and methods also provide a light that is impact- and vibration-resistant, so that it can continue operating in rough conditions.

The present invention is directed to a portable lighting unit releasably connectable to a fixture, such as a rail, tubing, cable, to provide auxiliary lighting to a desired area. In one embodiment, the lighting unit comprises a first housing comprising a first pair of opposing notches, a second housing comprising a second pair of opposing notches, the first and second housings being attachable together with the notches cooperating to receive the fixture through the notches, a photovoltaic cell mounted to one of the first and second housings, a light source mounted to one of the first and second housings, and at least one rechargeable battery housed within one of the first and second housings, the at least one rechargeable battery electrically coupled to the photovoltaic cell and to the light source. In one embodiment, the lighting unit includes a microcontroller electrically coupled to the photovoltaic cell and the light source. In a further embodiment, the lighting unit includes a lid having a waterproof chamber configured to house the photovoltaic cell, wherein the lid is detachably connectable to one of the first and second housings. In yet another embodiment, the lighting unit includes a casing having a waterproof cavity configured to house the light source, wherein the casing is rotatably receivable in an opening in one of the upper and lower housings.

In another embodiment, the lighting unit includes a grommet having an axial length removably receivable within the first and second pairs of notches, the grommet configured to receive a portion of the fixture. In one embodiment, the grommet further comprises a narrow longitudinal slit extending along the axial length, wherein the first and second housings are configured to close the slit. In a further embodiment, the grommet further comprises first and second opposite bulbous ends, wherein the first and second pairs of notches are configured to compress the bulbous ends. In yet a further embodiment, the lighting unit includes a switch electrically coupled to the light source, wherein the switch may be selectively operated for actuating the light source. In another embodiment, the portable lighting unit includes a lens, such as a Fresnel lens, configured to direct light to an exterior surface of the photovoltaic cell.

A method for installing and operating a lighting unit according to an embodiment of the present invention is provided. In one embodiment, the method comprises attaching first and second housings to each other around a fixture, the first and second housings having opposing first and second openings configured to receive the fixture, attaching a solar panel to the first housing, attaching a light source to one of the first and second housings, and electrically coupling the solar panel to the light source. In one embodiment, the method includes providing a grommet having a longitudinal opening with an inner diameter substantially equal to an outer diameter of the fixture, and passing the fixture through the longitudinal opening in the grommet, wherein attaching the first and second housings to each other comprises attaching the housings around the grommet. In yet another embodiment, the method includes rotating the light source, such as between 10° and 90°, with respect to the second housing module into a desired orientation. In one embodiment, the method includes coupling a microcontroller to the solar panel and the light source, the microcontroller programmed with a plurality of lighting modes. In a further embodiment, the method includes coupling a switch to one of the first and second housings, wherein the switch is configured to electronically communicate with the microcontroller. In one embodiment, the method further comprises activating the switch to select a desired one of the plurality of lighting modes, such as setting the light source to illuminate for a predetermined period of time, setting the light source to illuminate during low ambient light, turning on and off the lights, and setting the color of the light emitted from the light source.

### BRIEF DESCRIPTION OF THE DRAWINGS

FIG. 1 is a perspective view of a boat with a lighting system according to an embodiment of the invention.

FIG. 2 is a perspective view of a lighting unit according to an embodiment of the invention, attached to a curved, tubular rail.

FIG. 3 is an exploded perspective view of a lighting unit according to an embodiment of the invention, attached to a cable.

FIG. 4 is a cut-away top view of a lighting unit according to an embodiment of the invention, attached to a rail.

FIGS. 5A-C are views of a bushing connected to a rail, according to an embodiment of the invention.

FIG. 6 is a simplified schematic diagram of a circuit for a solar-powered light, according to an embodiment of the invention.

FIGS. 7A-7C are exploded and cut-away views of a lighting unit according to an embodiment of the invention.

FIGS. 8A-8B are upper and lower perspective views of a light source assembly for a lighting unit according to an embodiment of the invention.

FIGS. 9A and 9B are exploded views of a lighting unit according to an embodiment of the invention.

FIG. 9C is a perspective view of a support tray according to an embodiment of the invention.

FIG. 10 is a cut-away side view of a lighting unit according to an embodiment of the invention.

FIG. 11A is a cut-away top view of a lighting unit according to an embodiment of the invention attached to a straight fixture.

FIG. 11B is a cut-away top view of a lighting unit according to an embodiment of the invention attached to a curved fixture.

FIG. 12 is a side view of a light collection unit including a lens according to an embodiment of the invention.

### DETAILED DESCRIPTION

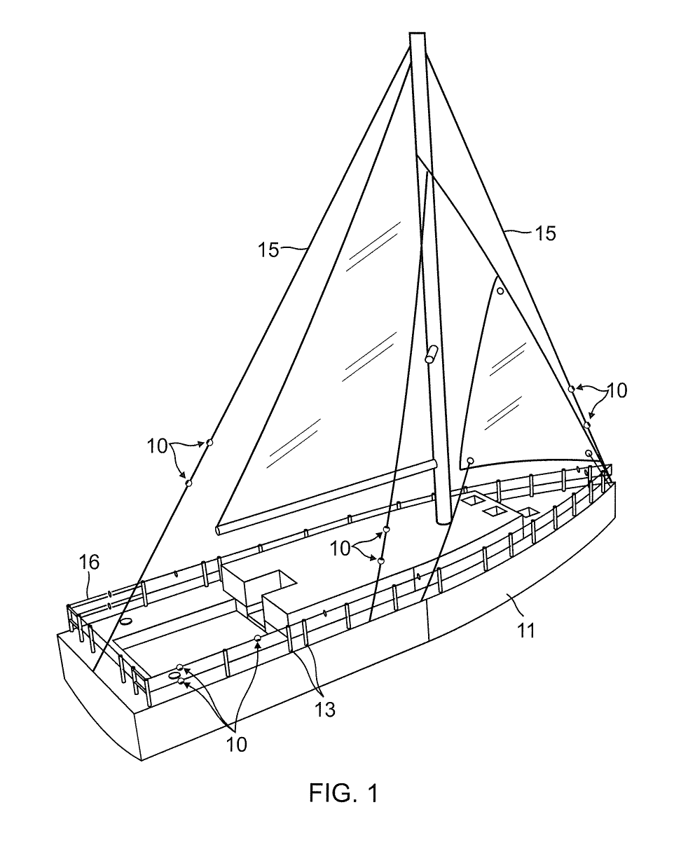

The present invention relates to lighting products, and more particularly to a lighting unit for an elongated support member on a boat. A boat with a lighting system according to an embodiment of the invention is shown in FIG. 1. The boat 11 includes elongated support members such as cables 15 and railings 16. Individual lighting units 10 according to an embodiment of the invention are shown attached to the cables and rails at various locations around the boat. These lighting units 10 provide additional lighting in areas that are often under-illuminated. For example, the railing 16 may be safety railing, which is found around the perimeter or gunnels of boats and is typically constructed from steel tubing. Some boats include tube railings at the bow and stern of the boat, and steel cables along the sides of the boat. Vertical members or stanchions 13 support the railing 16 or the cables that are strung from stanchion to stanchion along the boat's perimeter. The lighting units may be attached to other elongated or tubular members around the boat, such as bars, stanchions, posts, wires, etc.

Safety railing is designed to protect boaters from falling overboard as they walk along a walkway inboard of the railing forward or aft. This walkway is often not illuminated, particularly on sailboats which have minimal electrical power. The handrails that run along the sides of cabins, across the full length of the transom or around the bow of the boat are also often not illuminated. The anchor, anchor windlass, and chain locker are often used at night and are typically surrounded by safety railing, but are also not illuminated. While boats often have deck lights mounted on the mast, use of these lights may destroy night-vision and/or violate lighting regulations while the boat is underway. Many boats lack generators and have limited battery power, and thus additional lighting along the boat is minimal or absent. Passing electrical wiring to these areas to install additional lighting is costly and susceptible to corrosion and electrical failure.

The lighting units 10 shown in FIG. 1 are self-contained lighting units that are easily and safely attachable to tubular members and fixtures anywhere along the boat, without the need for additional electrical wiring. Any desired number of lighting units 10 can be provided along the boat 11, such as along walkways, cables, safety railings, etc.

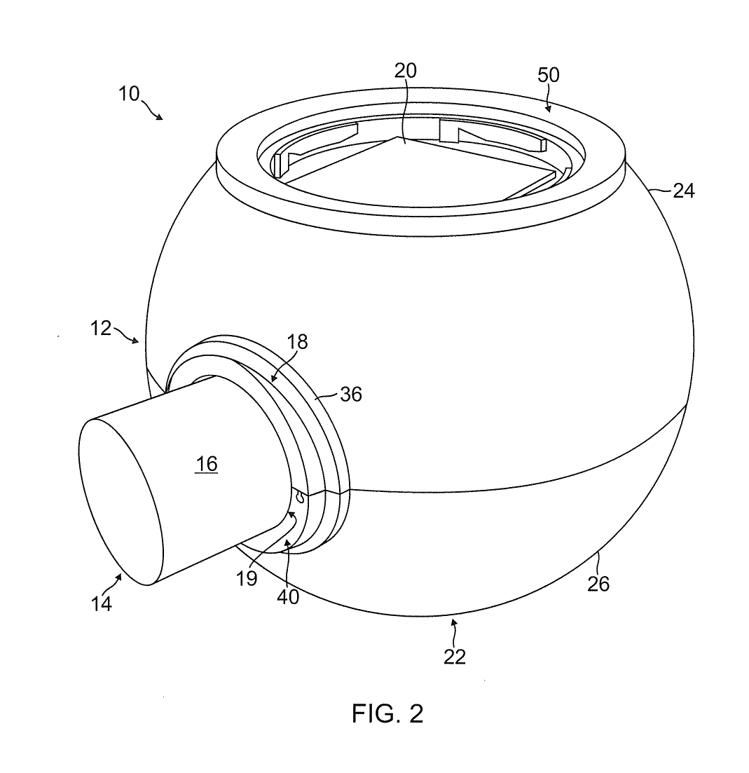

A lighting unit 10 according to an embodiment of the invention is shown in FIG. 2. The lighting unit includes a housing 12 that captures a fixture 14 such as a railing 16. The railing 16 passes through the housing 12, entering and exiting the housing through opposite first and second openings 18 in the housing 12. The housing 12 is thus firmly secured to the railing. In the embodiment shown, the lighting unit 10 includes a solar panel 20 seated in a top portion of the housing, and a light source 22 (not visible in FIG. 2) mounted to a bottom portion of the housing. In operation, the lighting unit 10 is secured to a fixture 14 on a boat, such as a handrail, guardrail, bar, cable, wire, or tubular member, at any location along the boat where additional lighting is desired. The cable may be a plastic coated wire, and the railing may be a hollow metal tubular railing. The solar panel operates to charge a battery and/or charge the light directly, and the light source is then operated to illuminate the area as desired.

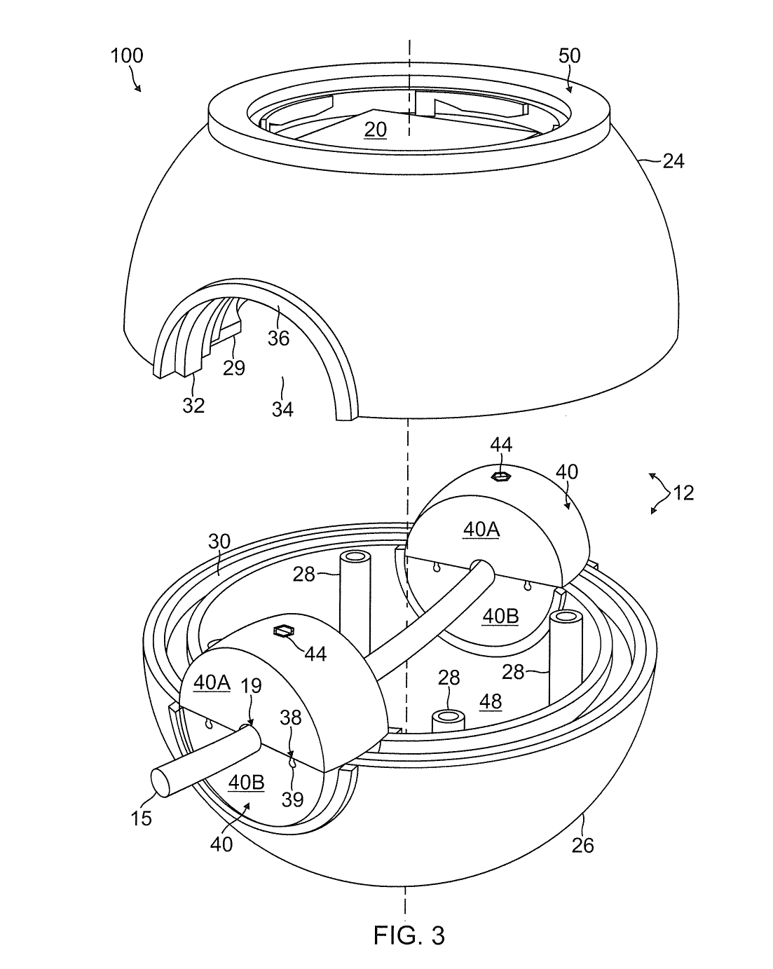

A lighting unit 100 according to an embodiment of the invention is shown in an exploded view in FIG. 3, for mounting to a cable or wire 15. The lighting unit 100 includes a housing 12 that is made up of two separable housing pieces or modules, an upper housing 24 and a lower housing 26. These two housing pieces attach to each other to form the housing 12. The upper and lower housings 24, 26 include mating components to attach the two pieces together, such as a groove 30 in one housing and mating ridge 32 in the other housing. These mating components provide a snap-fit or friction-fit connection. In some embodiments, the two housing pieces are attached together by other mechanical connectors, such as bolts, clips, snaps, screws, and other suitable connectors. For example, as shown in FIG. 3, the lower housing 26 includes threaded openings 28 for receiving screws (not shown) that are passed through openings in a ledge 29 in the upper housing 24. The screws thus attach the upper housing 24 to the lower housing 26. Additional screws may be provided over the cable or railing, to tighten the housing 12 and prevent it from rotating about the cable or railing.

The upper and lower housings each have a pair of recesses 34 on opposite sides of the housings. When the upper and lower housings are attached together, the recesses 34 on each housing align to form the first and second openings 18. In one embodiment, a rim 36 is provided around the opening 18.

In one embodiment, the lighting unit 100 includes a pair of bushings 40 that are received into the two openings 18 in the housing. The bushings 40 provide an interface between the housing 12 and the tubular fixture 14. In particular, the bushings 40 fit around the fixture and rotate with respect to the housing, to accommodate fixtures of various diameters, shapes, curves, and bends. As shown in FIG. 3, the bushings 40 each include two parts, an upper bushing portion 40A and a lower bushing portion 40B. These two portions or pieces of the bushing are separable to enable the bushing to be passed over and around the fixture, such as the cable 15. The two bushing portions then attach to each other to secure the bushings 40 and the housing 12 around the fixture. The bushing portions cooperate to form an opening 19 through the center of the bushing 40, for passage of the fixture such as a cable or railing.

The first bushing portion 40A includes two projections 38 that are shaped and sized to fit into two corresponding recesses 39 in the second bushing portion 40B. To attach the bushings to the fixture, the first bushing portion 40A is placed on top of the fixture, and the second bushing portion 40B is placed below the fixture, offset from the first bushing portion 40A. The two pieces are then slid together, such that the projections 38 slide into the recesses 39. The bushing 40 is then trapped around the fixture. Once the bushings are attached to the fixture, they can be further secured by screws 44, which are tightened to prevent the bushing from rotating or spinning around the cable 15 (or other fixture).

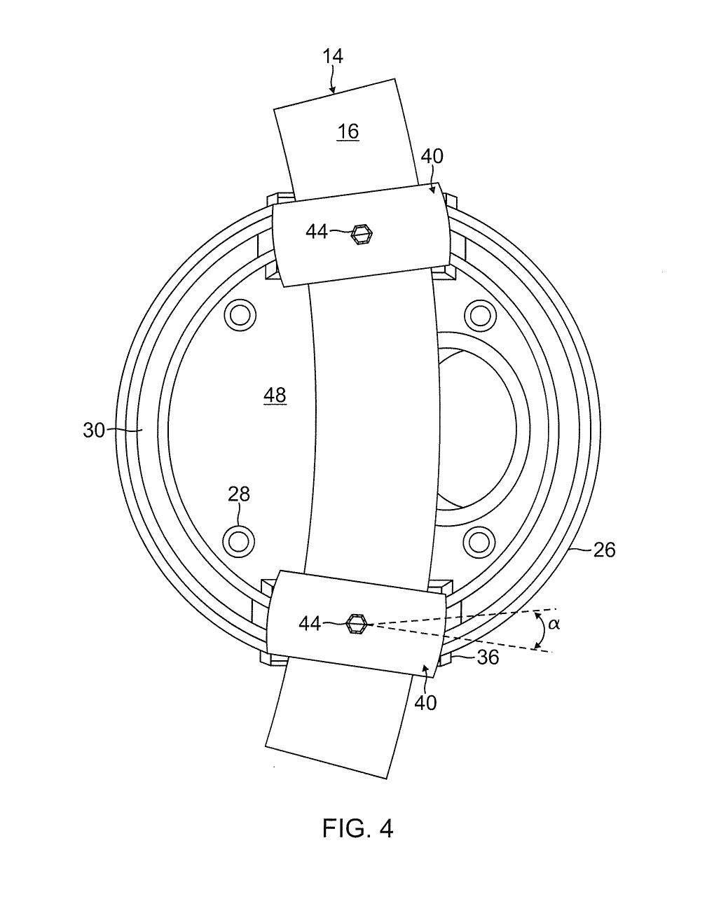

Once the bushings 40 are attached to the fixture, the upper and lower housings 24, 26 are then attached to each other around the bushings 40. The bushings 40 fit within the recesses 34 in the two housings, in a ball-and-socket type mating. That is, the recesses 34 are shaped to receive the bushings, and the bushings can rotate within the recesses. This rotation enables the housing 12 to be attached around a curved or bent fixture. For example, in FIG. 4, the lower housing 26 is shown with bushings 40 attached around a rail 16. The rail 16 is curved, and the bushings are each rotated to accommodate the curved rail as it passes through the housing 12. In FIG. 4, the bushings are rotated from a straight position by angle α.

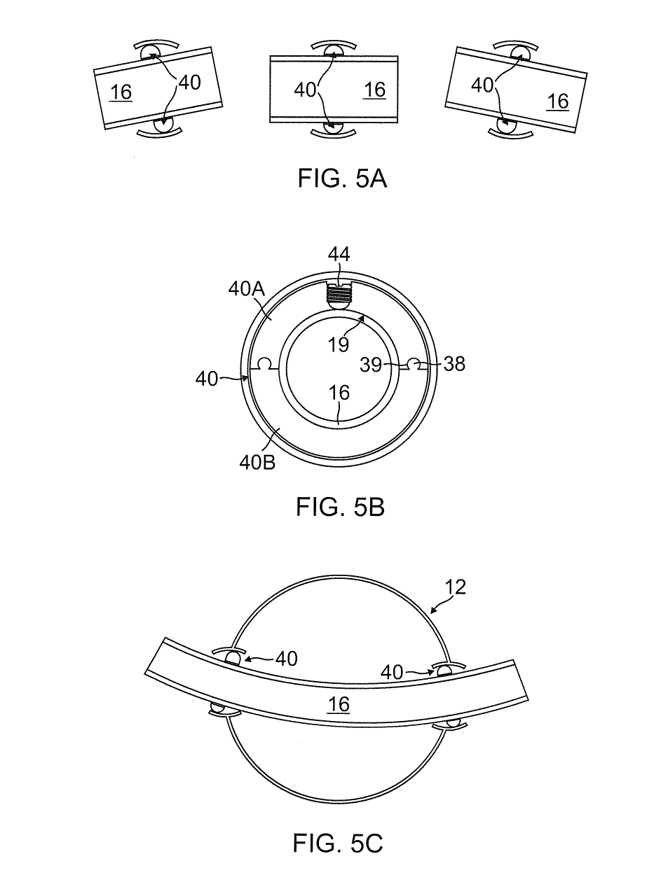

The rotation of the bushings about the fixture is shown in more detail in FIGS. 5A-5C. FIG. 5A shows a rail 16 passing through a bushing 40 at various angles. The bushing 40 rotates within the socket created by recesses 34, to accommodate the shape of the rail 16. A top view of a curving rail 16 passing through two bushings 40 is shown in FIG. 5C. FIG. 5B shows a side cross-sectional view of the bushing 40, with the tightening screw 44 and mating projections 38 and recesses 39. The bushing 40 fits snugly around the rail 16. In various embodiments, bushings of various sizes can be provided to fit around railings, cables, bars, and other fixtures of various diameters and cross-sections.

The bushings 40 may be slightly compressed within the recesses 34, when the housing pieces are attached, in order to provide a snug fit. Additionally, the bushings may have a textured outer surface for a friction fit.

Referring again to FIGS. 3-4, the lower housing 26 includes a generally hollow interior 48 for carrying the components of the lighting system. Additional details regarding this hollow interior and the lighting components are provided further below. In one embodiment, the lower housing 26 and upper housing 24 join together to form the hollow interior 48.

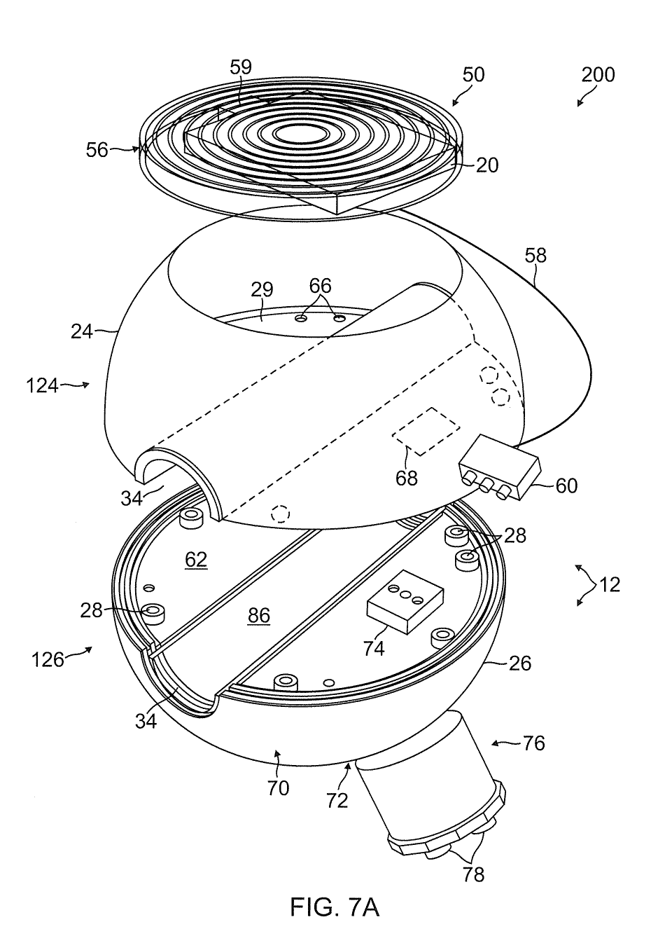

In one embodiment, the lighting unit 10, 100 is powered by a solar panel 20. As shown in FIGS. 2 and 3, the solar panel 20 is mounted in a top surface of the upper housing 24. The top surface of the upper housing 24 includes a recessed area where the solar panel 20 is seated. In one embodiment, the solar panel 20 is provided in a separate solar panel unit 50, which is removable from the upper housing 24 (see FIG. 7A). The solar panel unit 50 is a self-contained, waterproof module that can be removed and replaced from the top of the upper housing 24. Additional details regarding this connection and the solar panel unit 50 are provided further below.

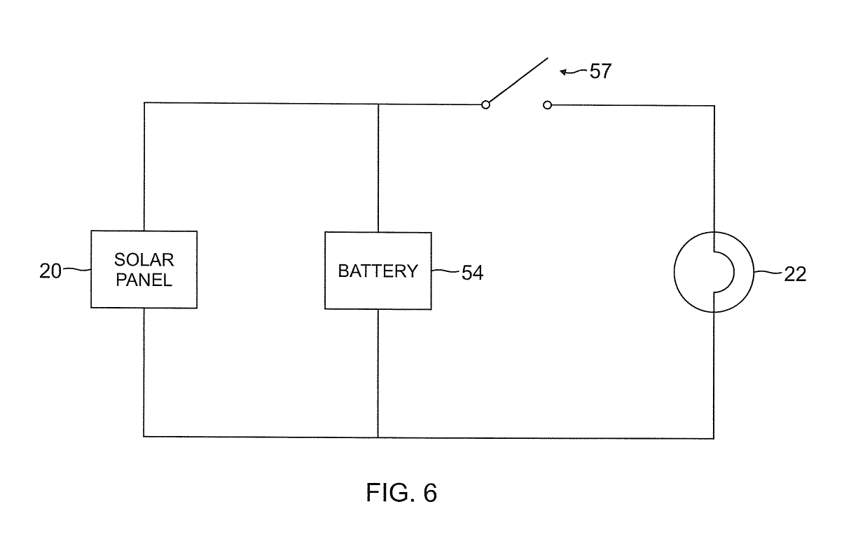

In one embodiment, the solar panel 20 is electrically coupled to an internal battery and to the light source. A simplified schematic diagram of a circuit according to an embodiment is shown in FIG. 6. The solar panel 20 is electrically coupled to an internal battery 54 and a light source 22. The battery 54 is rechargeable, and may include multiple batteries. A switch 57 is provided between the solar panel and the light source. The light 22 may also be coupled to a light sensor 59 (shown in FIG. 7A), so that the light is turned on and off based on the level of light sensed by the light sensor. For example, when ambient light levels are low, the light sensor activates to turn the light source on. When light levels increase, the light sensor turns the light source off. This allows the light 22 to automatically turn on at sunset and turn off at sunrise. The circuit may also include a timer so that the light can be pre-programmed to turn on and off at desired times or intervals. The circuit may be provided with a receiver for receiving radio transmissions, so that the switch can be operated by remote control.

A lighting unit 200 according to an embodiment of the invention is shown in FIGS. 7A-7C. FIG. 7A shows the lighting unit 200 in an exploded view, with the lighting unit separated into four main modules or units. This modular system seals the internal components from exposure to the environment (including corrosive salt water), and fits together quickly and easily to create a self-contained lighting unit.

At the top of FIG. 7A is the solar panel module or unit 50. The solar panel unit 50 includes a waterproof chamber 56 that houses the solar panel 20. The water proof chamber 56 completely seals the solar panel 20 from the outside environment. The top surface of the solar panel unit 50 is transparent, allowing incoming sunlight to impact the solar panel 20. One or more electrical leads or wires 58 extend from the solar panel 20 and are passed out of the chamber 56 through a waterproof seal on the bottom side of the chamber. The wires end in a plug 60. The plug 60 is a waterproof plug that connects to the electrical system to charge the battery and light source, as described more fully below.

Moving down through FIG. 7A, the next module is the upper housing module or unit 124, which includes the upper housing 24, with its recesses 34 (described earlier). The upper housing 24 includes a top opening 64, which receives the solar panel unit 50. The solar panel unit 50 and top opening 64 may include mating connectors, such as a bayonet-style twist-and-lock connection, a snap fit, or other mechanical connectors. The solar panel unit 50 seals the top opening 64. A rubber gasket may be provided on either the solar panel unit 50 or along the opening 64 to further seal the opening 64.

The upper housing module 124 includes a lower surface 29, such as a plate or ledge, extending across the bottom side of the upper housing module 124. This surface 29 includes openings 66 for screws, which are passed through the openings 66 and threaded to the lower housing 26 to connect the upper and lower housings 24, 26 together, before the solar panel unit 50 is inserted into the top opening 64. The surface 29 also includes an opening 68 for the waterproof plug 60. The plug 60 passes through the opening into the lower housing, as described further below. The interior of the upper housing 24 is generally hollow and, in one embodiment, empty.

Below the upper housing module 124 is the lower housing module 126. The lower housing module 126 includes the lower housing piece 26, an upper plate or lid 62, and two separate waterproof chambers 70, 72 that are isolated from each other. The lid 62 of the lower housing module 126 includes threaded openings 28 that receive screws through the openings 66 in the upper housing module 124, to connect the upper and lower housing modules together. The upper and lower housing modules attach together to create the complete housing 12.

The first water proof chamber is the electronics chamber 70. The electronics chamber 70 is defined within the lower housing 26, and the lid 62 and is completely sealed from exposure to the outside environment. The electronics chamber 70 includes the electronic components of the lighting system, except for the solar panel, the light sensor, and the light source itself. That is, the electronics chamber includes the battery, switch, timer, and printed circuit board. A waterproof plug 74 extends up from the chamber 70 to receive the waterproof plug 60 from the solar panel. The connection of the plugs 60 and 74 electrically couples the solar panel to the battery and light source.

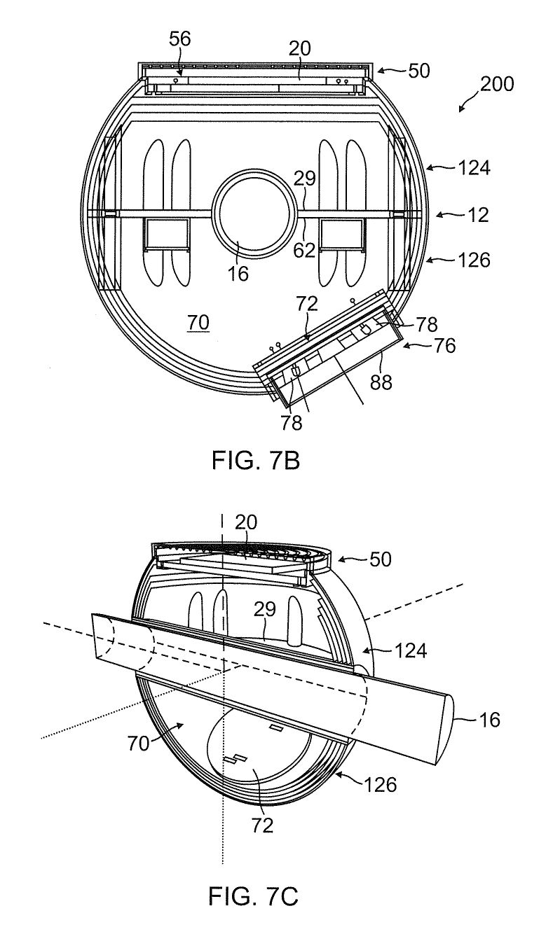

The second waterproof chamber is the light source chamber 72. In this embodiment, the light source chamber 72 receives a separate light source module or unit 76 that houses the LED lights 78 or other light bulbs or light sources. The light source chamber 72 faces out from the lower housing 126 and has an open front side. The light source module 76 passes through this front opening and fits into the light source chamber 72. With this arrangement, the light source module 76 can be removed and replaced from the lighting unit 200 without the need to open the two housing modules 124, 126. The light source module 76 fits separately into the open light source chamber 72 from outside of the sealed electronics chamber 70. When the light module 76 is inserted into the chamber 72, the light module 76 seals the chamber from the outside environment, providing a waterproof seal. A rubber gasket may be included on the module 76 to provide a seal against the chamber 72, to prevent moisture from entering the chamber 72. In one embodiment, the back surface of the light module 76 includes electrical wires and/or contacts 84 (see FIG. 8A) that contact corresponding electrical contacts at the back of the light source chamber 72, such that the electric circuit is completed when the light module 76 is fitted into the chamber 72. Placing the light module 76 into the chamber 72 electrically couples the LED lights 78 to the electrical circuit (see FIG. 6). The light module 76 and chamber 72 are shown provided on the lower housing 126, but they could be provided on the upper housing 124 instead or in addition, with an additional waterproof plug extending through the lid 62 to electrically couple to the battery and other components in the electronics chamber 70.

The solar panel unit 50, upper housing unit 124, lower housing unit 126, and light source unit 76 are shown attached together into the lighting unit 200 in FIGS. 7B-7C. The lighting unit 200 may be used in conjunction with the bushings 40, or may be attached directly to a fixture such as a cable or railing. The modular nature of the lighting unit 200 enables the various components to attach together while remaining sealed from the external environment, and enables different components to be easily removed and replaced. The solar panel module 50 can be removed and replaced if necessary, without removing the lighting unit 200 from a fixture to which it is attached. The light source can also be removed and replaced without removing the lighting unit 200 from the fixture. The light source module 76 can be removed, and a different light source module with different color lights or different color combinations can be replaced. During these operations, the electronics chamber 70 remains safely sealed from the external environment. The battery, switch, and other electric circuitry is safely protected from saltwater, wind, sun, and other environmental exposures. In this embodiment, the fixture (such as a straight or curved railing or cable) passes over the lid 62, above the electronics chamber 70, and the fixture does not enter into or pass through the electronics chamber.

The light source may include one or more lamps such as LED (light-emitting diode) lights 78 of varying colors or color combinations (such as red, green, blue, and/or white). LED lights may also be provided within the upper and lower housings 24, 26 to make them glow. In other embodiments, the lamp(s) include other types of light bulbs or light sources instead of or in addition to LED's, such as, for example, organic LED's (OLED).

In one embodiment, the LED lights in the light source unit 76 are gimbaled to the lower housing unit 126 so that the LED lights 78 can be aimed by pivoting or rotating them within the light source unit 76, as shown in FIGS. 8A-8B. In the embodiment shown, the light source unit 76 includes six LED lights 78 of varying colors. The LED lights 78 are mounted by a gimbal 80 to an outer ring 82, which fits into the light source chamber 72 on the lower housing unit 126. The LED lights 78 can be pushed to rotate about pins 81, 83 in order to aim the lights in the desired direction. Optionally, the LED lights may also be rotated by twisting the outer ring 82 about axis A (see FIG. 8B). Twisting the lights in this fashion may activate the switch 57 to turn the lights on and off, or to alternate between different colors, turning different colored LED lights on and off. The switch 57 may be located around the perimeter of the light module 76 so that twisting the module engages and disengages the switch.

Although not shown in FIGS. 8A-8B, the light module 76 includes an outer cover or shield 88 (see FIG. 7B) that maintains a water proof seal when the light module 76 is fitted into the chamber 72 (see FIG. 7A).

Referring again to 7A, the lighting unit 200 is shown with a lid 62 that provides a passage 86 for a straight fixture such as a straight railing. In the embodiment shown, the bushings are optional, as the upper housing module 124 may be attached directly to the lower housing module 126, capturing a straight railing through the passage 86. However, in other embodiments, the two housing modules 124, 126 and the lid 62 can be shaped to provide additional clearance to receive a curved fixture, such as a curved railing. Additionally, the lid can be recessed and bushings may be provided along with the lighting unit 200 to accept a curved fixture between the housing pieces.

In one embodiment, a portable lighting system is provided, which includes a lighting unit attachable around a rail, tubing, cable, or other fixture, and optionally, one or more pairs of bushings. The pairs of bushings each have an internal opening of a particular shape and size to receive a fixture such as a cable or tubular railing. The appropriate pair of bushings can be used with the lighting unit to attach the lighting unit to the particular fixture. For example, the portable lighting system may include a lighting unit, a first pair of bushings with a first opening, and a second pair of bushings with a second opening of a different shape and/or size. The bushings are interchangeable with the lighting unit.

The lighting unit described herein may be powered by a solar panel, or alternatively, may be powered by induction coils that surround an electrified cable. An embodiment of the present invention utilizes uses batteries that are charged by wireless energy transfer or induction. This embodiment utilizes the magnetic field created by the wire to which it is attached to charge the batteries through inductive coupling.

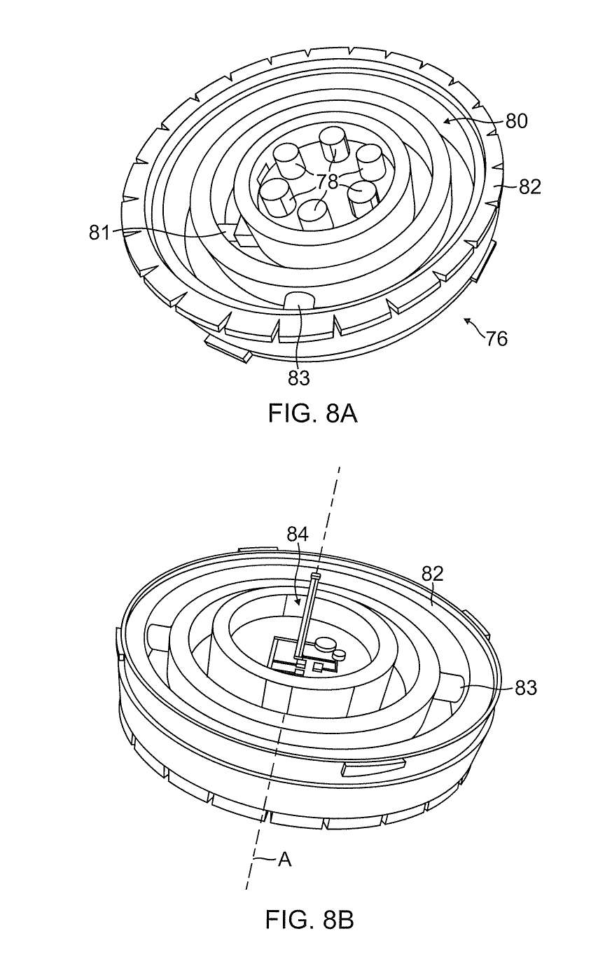

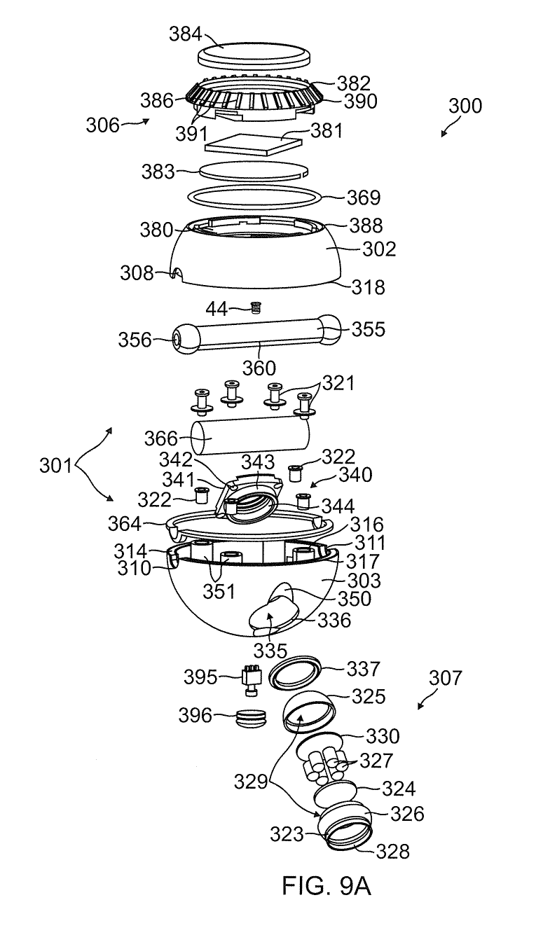

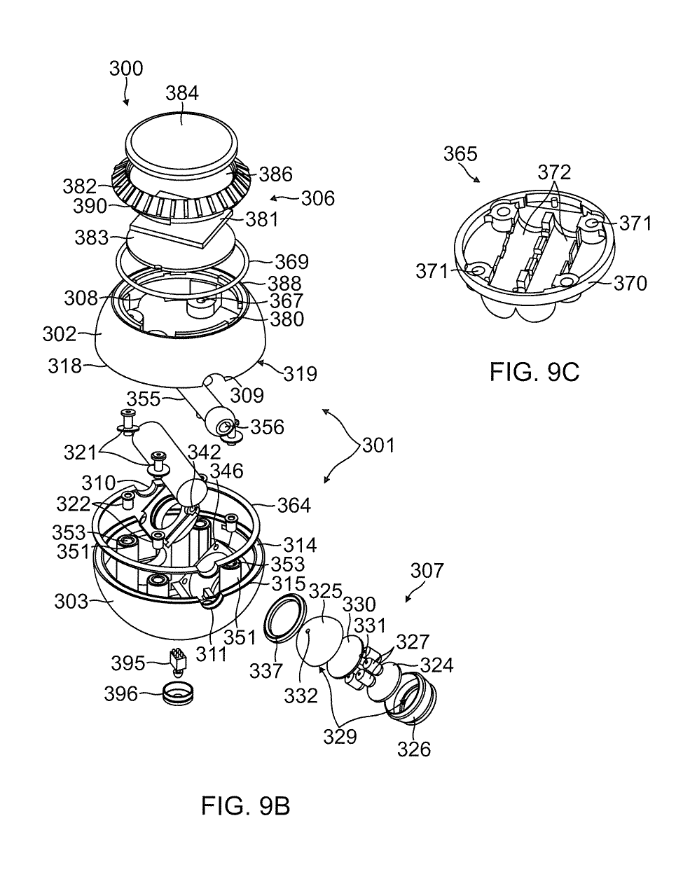

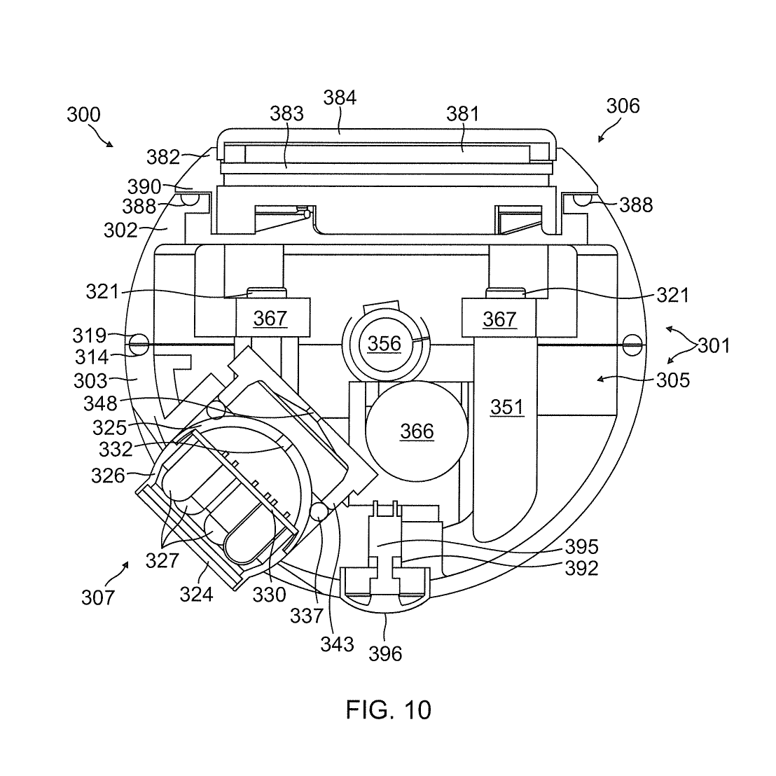

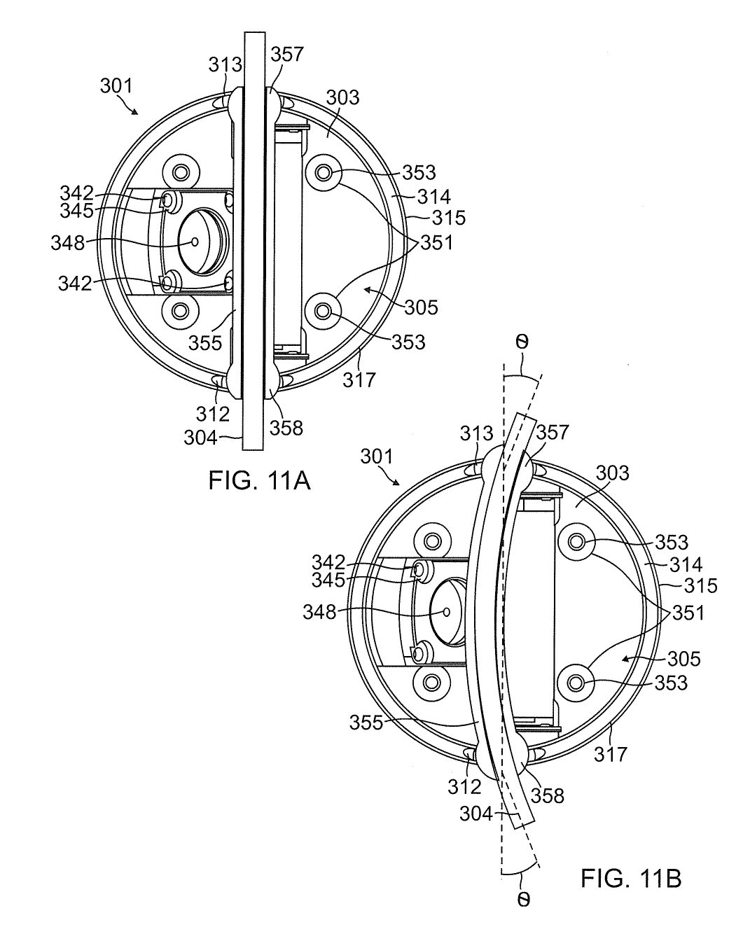

A lighting unit 300 according to another embodiment of the present invention is illustrated in FIGS. 9A and 9B. The lighting unit 300 comprises a housing 301 having an upper housing 302 detachably connectable to a lower housing 303. The upper and lower housings 302, 303 are separable and configured to move between a detached position and an attached position (see FIG. 10) in which the lighting unit 300 is secured to a fixture 304 (see FIGS. 11A, 11B), such as a handrail, guardrail, bar, cable, wire, or tubular member, at any location where additional or auxiliary lighting is desired. As illustrated in FIG. 1, the lighting unit 300 may be attached to cables 15 and railings 16 at various locations around a boat 11. In the closed position, the upper and lower housings 302, 303 form a spheroid cavity 305 configured to house a variety of components, described in detail below. In the illustrated embodiment of FIGS. 9A and 9B, the upper housing 302 is configured to receive a light collection assembly 306, and the lower housing 303 is configured to receive a lighting assembly 307. Additionally, the upper and lower housings 302, 303 both contain opposing arcuate notches 308, 309 and 310, 311, respectively. The arcuate notches 308, 309 in the upper housing 302 are configured to align with the arcuate notches 310, 311 in the lower housing 303. Together, the arcuate notches 308, 309, 310, 311 in the upper and lower housings 302, 303 form opposite first and second circular openings 312, 313 (see FIGS. 11A, 11B) through which the fixture 304 may extend through the housing 301.

In the illustrated embodiment of FIGS. 9A and 9B, the lower housing 303 includes an annular channel or groove 314 extending continuously around the periphery of an upper edge 315 of the lower housing 303. The channel 314 extends between inner and outer surfaces 316, 317 of the lower housing 303. In one embodiment, the channel 314 is generally U-shaped. Similarly, a lower edge 318 of the upper housing 302 includes an annular channel or groove 319 (see FIG. 10) configured to align with the channel 314 in the lower housing 303. The channels 314, 319 also extend along the arcuate notches 308, 309, 310, 311 in the upper and lower housings 302, 303 to create a continuous sealing groove. The channels 314, 319 in the upper and lower housings 302, 303 are configured to receive a gasket 364, such as an o-ring, configured to prevent water from entering into the interior cavity 305 of the housing 301. In one embodiment, the gasket 364 may be bonded into either the channel 319 in the upper housing 302 or the channel 314 in the lower housing 303. The gasket 364 is configured to protrude above the upper edge 315 of the lower housing 303 and thereby extend into the channel 319 in the upper housing 302 when the upper housing 302 is connected to the lower housing 303. Moreover, the upper and lower housings 302, 303 are configured to compress the gasket 364 such that the compressed gasket 364 fills the channels 314, 319 in the upper and lower housings 302, 303. The gasket 364 may be formed from any suitably resilient and compressible material, such as silicone, rubber, or neoprene.

The upper and lower housings 302, 303 may comprise any suitably durable material, such as plastic, aluminum alloy, or polyvinyl chloride (PVC). The upper and lower housings 302, 303 may be formed by any suitable process, such as stamping, molding, welding, or rapid prototyping using additive manufacturing (e.g., laser sintering or stereolithography). In one embodiment, the upper and lower housings 302, 303 may include a protective sleeve (not shown). The protective sleeve may comprise a separate shell bonded to the exterior of the upper and lower housings 302, 303 or may be directly applied to the exterior by any suitable process, such as vacuum metalizing. The upper and lower housings 302, 303 may be vacuum metalized with any suitable metal, such as copper, nickel, or chrome.

With continued reference to the embodiment illustrated in FIGS. 9A and 9B, the lighting assembly 307 comprises upper and lower shells 325, 326, respectively, configured to house a plurality of lights 327, such as LEDs. In the illustrated embodiment, the lighting assembly 307 includes six LEDs. It will be appreciated, however, that the lighting assembly 307 may include any suitable number of lights 327, such as between one and ten, depending upon the desired illumination and battery life of the lighting unit 300. The LEDs may be provided in varying colors (e.g., red, blue, green, and white). In one embodiment, the lighting assembly 307 includes one white LED, three green LEDs, one blue LED, and one red LED. The red LEDs may be provided to aid a user's vision at night. The fovea centralis (i.e., the center 1.5% of the retina), which is responsible for sharp central vision, contains a high density of red-sensitive cones, and therefore the red LEDs aid the user's vision at night.

The upper and lower shells 325, 326 may be secured together by any suitable means, such as with a threaded connection or a snap fit connection. Together, the upper and lower shells 325, 326 form waterproof casing having a generally spherical cavity 329, although the shells may be any other suitable shape, such as cuboid, and still fall within the spirit and scope of the present invention. The lower shell 326 also includes an opening 328, such as a circular opening, configured to reveal the lights 327. Moreover, the opening 328 in the lower shell 326 may be configured to receive a translucent or transparent cover 324. The lower shell 326 may also include an annular lip 323 extending around the opening 328 to receive the cover 324. In one embodiment, the cover 324 is configured to be inserted up through a lower end of the opening 328 in the lower shell 326. In another embodiment, the cover 324 is configured to be inserted down through an upper end of the opening 328 in the lower shell 326. The cover 324 is configured to prevent water from entering the cavity 329 between the upper and lower shells 325, 326, which could damage the lights 327 housed in the cavity 329. The cover 324 may also be configured to provide a hermetic seal. The cover 324 may be secured to the opening 328 in the lower shell 326 by any suitable means, such as bonding or welding (e.g., friction stir welding). Furthermore, the cover may be provided in various colors, such as red, blue, or green. In one embodiment, the lower shell 326 may be a transparent cover, and the lighting assembly 307 may be provided without a separate cover. The lighting assembly 307 also includes a terminal board 330 housed in the upper and lower shells 325, 326. One side of the terminal board 330 is configured to receive terminal ends 331 of the lights 327, and an opposite side of the terminal board 330 is configured to receive wires connecting the lighting assembly 307 to the light collection assembly 306, described below. The terminal board 330 may include a variety of electronic components configured to actuate the LED lights 327. The upper shell 325 of the lighting assembly 307 includes an opening 332 (see FIG. 9B) configured to allow the wires from the light collection assembly 306 to pass through the upper shell 325 and connect to the terminal board 330.

As illustrated in FIGS. 9A and 9B, the lighting assembly 307 is adjustably received in an opening 335 in the lower housing 303. In one embodiment, the widest portion of the upper and lower shells 325, 326 is wider than the opening 335 in the lower housing 303 to prevent the lighting assembly 307 from inadvertently dislodging from the lower housing 303. That is, an inner wall 336 of the opening 335 in the lower housing 303 engages the exterior of the lower shell 326 and thereby prevents the lighting assembly 307 from falling out of the opening 335. Accordingly, the lighting assembly 307 is configured to be installed from the interior of the lower housing 303. When the lighting assembly 307 is installed, a portion of the lower shell 326 protrudes from the opening 335 in the lower housing 303, as illustrated in FIG. 10 (i.e., a portion of the lower shell 326 extends beyond the outer surface 317 of the lower housing 303).

The lighting assembly 307 may also include an annular gasket 337, such as an o-ring, configured to prevent water from entering into the interior cavity 305 of the housing 301 through the opening 335 in the lower housing 303. The gasket 337 is configured to encircle a portion of the outer surface of the upper shell 325. Accordingly, the gasket 337 provides a seal between the outer surface of the lighting assembly 307 and the inner wall 336 of the opening 335 in the lower housing 303. When the lighting assembly 307 is assembled with the lower housing 303, the annular gasket 337 is configured to compress between the lower housing 303 and the upper shell 335 of the lighting assembly 307, as illustrated in FIG. 10 and described in further detail below.

With continued reference to the embodiment illustrated in FIGS. 9A, 9B, and 10, the lighting unit 300 may include a pressure plug 340 configured to compress the annular gasket 337 between the upper shell 325 of the lighting assembly 307 and the lower housing 303. In the illustrated embodiment, the pressure plug 340 is housed in the interior portion of the lower housing 303. The pressure plug 340 comprises a base plate 341 having a plurality of attachment holes 342, an annular protrusion 343 extending downward from the base plate 341, and a recess 344 configured to receive a portion of the upper shell 325. The attachment holes 342 in the pressure plug 340 are configured to receive a plurality of fasteners (not shown), such as button head screws, securing the pressure plug 340 to the lower housing 303. As illustrated in FIG. 9B, the lower housing 303 includes a plurality of openings 346, such as blind bore holes, corresponding to the openings 342 in the pressure plug 340. The fasteners securing the pressure plug 340 to the lower assembly 303 are configured to extend through the openings 342 in the base plate 341 and into the openings 346 in the lower housing 303. Head portions of the fasteners are configured to abut the base plate 341 of the pressure plug 340. In one embodiment, the head portions of the fasteners are received in recesses 345 in the pressure plug 340. In an alternate embodiment, the pressure plug 340 may be connectable to the lower housing 303 by any other suitable means, such as bonding, a threaded connection, or with a bayonet-style connection.

Still referring to FIG. 10, the annular protrusion 343 on the pressure plug 340 is configured to extend into the opening 335 in the lower housing 303 and thereby compress the gasket 337 against the upper shell 325 to create a watertight seal. The annular protrusion 343 on the pressure plug 340 is substantially the same size and shape as the annular gasket 337. The fasteners extending through the pressure plug 340 provide a compressive force against the annular gasket 337. In one embodiment, the lighting unit 300 may include a compression spring (not shown) configured to bias the pressure plug 343 into the opening 335 in the lower housing 303 to create a watertight seal. Additionally, the outer diameter of the annular protrusion 343 on the pressure plug 340 is substantially the same as the inner diameter of the opening 335 in the lower housing 303 such that the annular protrusion 343 is configured to provide a press fit seal. The recess 344 in the pressure plug 340 is configured to receive a portion of the upper shell 325. In one embodiment, the recess 344 in the pressure plug 340 is configured to substantially match the contour of the upper shell 325 of the lighting assembly 307 (e.g., the recess 344 may be generally hemispherical). The pressure plug 340 also biases the lighting assembly 307 into the opening 335 in the lower housing 303 such that an outer surface of the upper or lower shell 325, 326 engages the inner wall 336 of the opening 335. The interface between the recess 344 and the upper shell 325 may also be configured to lock the lighting assembly 307 into a desired orientation. In one embodiment, the orientation of the lighting assembly 307 may still be adjustable after the pressure plug 340 is installed. The pressure plug 340 also includes an opening 348 configured to permit the wires to extend between the terminal board 330 in the lighting assembly 307 and the light collection assembly 306.

With reference again to FIG. 9A, the outer surface 317 of the lower housing 303 may include grooves or dimples 350 configured to assist the user in adjusting the position of the lighting assembly 307 such that the lighting unit 300 illuminates the desired area. As illustrated in FIG. 9A, the dimples 350 may be oriented around the periphery of the opening 335 in the lower housing 303. In one embodiment, the lower housing 303 includes opposing first and second dimples 350. The first and second dimples 350 may be disposed 180° apart around the opening 335. In one embodiment, the lighting assembly 307 is configured to adjust approximately 90° in the vertical direction and approximately 90° in the horizontal direction. It will be appreciated, however, that the adjustability of the lighting assembly 307 is not limited to the values recited above, and the lighting assembly 307 may be configured to rotate any desired degree in the horizontal and vertical directions. In use, the user may first adjust the lighting assembly 307 into the desired position before installing the pressure plug 340. The user may then install the pressure plug 340 to lock the lighting assembly 307 into the desired orientation. Although the lighting assembly 307 is illustrated in the lower housing 303, in an alternate embodiment the lighting assembly 307 may be provided in the upper housing 302 such that the LED lights 327 are configured to project light upward.

With continued reference to the embodiment illustrated in FIGS. 9A and 9B, the lower housing 303 includes a plurality of cylindrical posts 351. In one embodiment, the lower housing 303 includes four cylindrical posts 351 arranged in a generally square pattern. The lower housing 303 may be provided with any other suitable number of cylindrical posts 351, such as between two and ten. The quantity and arrangement of the cylindrical posts 351 is designed to supply evenly distributed compression on the gasket 364 between the upper and lower housings 302, 303. Each of the cylindrical posts 351 include an axial opening 353, such a smooth blind bore or an internally threaded bore, configured to receive a plurality of fasteners 321 securing the upper housing 302 to the lower housing 303. The upper portion of the cylindrical posts 351 may also include an annular groove (not shown) such that the outer diameter of the upper portion of the cylindrical posts 351 is smaller than the outer diameter of the lower portion of the cylindrical posts 351. In one embodiment, the upper portion of the cylindrical posts 351 are configured to extend up into fastener receptacles, described below. The cylindrical posts 351 may also include threaded inserts 322 configured to receive a portion of the fasteners 321 securing the upper housing 302 to the lower housing 303. The lighting unit 300 may also include washers configured to secure the fasteners 321 to the fastener receptacles (i.e., the washers may be configured to capture the fasteners 321 in the fastener receptacles). The washers may be formed from any suitable material, such as polyethylene terephthalate (PET) or plastic.

With reference now to FIGS. 9A, 9B, and 11A, 11B, the lighting unit 300 may include a grommet 355 configured to receive a portion of the fixture 304 (e.g., rail, cable, or wire) to which the lighting unit 300 is secured. In FIG. 11A, the grommet 355 is illustrated receiving a straight segment of the fixture 304 passing through the housing 301. In FIG. 11B, the grommet 355 is illustrated receiving a curved portion of the fixture 304 passing through the housing 301. Accordingly, the grommet 355 is sufficiently flexible to accommodate either a curved segment or a straight segment of the fixture 304 extending through the housing 304. Specifically, the grommet 355 is configured to rotate an angle θ within the opposite first and second openings 312, 313 in the housing 301 to accommodate the curved fixture 304. The grommet 355 is configured to rotate or bend an angle θ with respect to a straight line extending through the opposite first and second openings 312, 313 in the housing 301. The grommet 355 may be configured to rotate into any desired angle θ within the openings 312, 313, such as 15°, 25°, 35°, or 45°, to accommodate the curved fixture 304. Moreover, although the embodiment of the grommet 355 illustrated in FIG. 11B is shown rotated within a horizontal plane, the grommet 355 my also be configured to rotate vertically or obliquely within the openings 312, 313. The grommet 305 is configured to prevent, or at least minimize, water propagation, such as by wicking, into the interior cavity 305 of the housing 301. The grommet 355 includes a longitudinal opening 356, such as a through bore, configured to receive the fixture 304 such that the grommet 355 surrounds the portion of the fixture 304 extending through the housing 301. In one embodiment, a sealant material, such as silicone, may be provided in the bore 356 to prevent water from wicking along the grommet 355. In the illustrated embodiment, the grommet 355 extends between the opposite first and second openings 312, 313 in the housing 301. In one embodiment, a portion of the grommet 355 extends beyond the outer surface 317 of the housing (i.e., opposite ends of the grommet 355 extend out of the opposite first and second openings 312, 313 in the housing 301). The grommet 355 also includes opposite first and second bulbous ends 357, 358. The bulbous ends 357, 358 of the grommet 355 are configured to engage the arcuate notches 308, 309, 310, 311 in the upper and lower housings 302, 303. In one embodiment, the bulbous ends 357, 358 of the grommet 355 are slightly larger than the opposite first and second openings 312, 313 in the housing 301 such that the bulbous ends 357, 358 of the grommet 355 are compressed when the upper housing 302 is connected to the lower housing 303. The bulbous ends 357, 358 of the grommet 355 are also configured to permit the grommet 355 to rotate within the openings 312, 313 to accommodate a curved fixture 304 extending through the housing 301.

The grommet 355 may also include a narrow longitudinal slit 360 extending along the entire length of the grommet to facilitate installation of the grommet over the fixture, as illustrated in FIG. 9A. In one embodiment, the upper and lower housings 302, 303 are configured to compress the grommet 355 such that the longitudinal slit 360 is closed when the upper and lower housings 302, 303 are secured together. That is, the upper and lower housings 302, 303 are configured to circumferentially contract the grommet 355 such that the narrow slit 360 is closed when the upper and lower housings 302, 303 are secured together. In one embodiment, the narrow longitudinal slit 360 may include an adhesive configured to bond the slit 360 in the closed position after the fixture 304 has been inserted through the bore 356 in the grommet 355. Moreover, the grommet 355 is configured to be oriented such that the longitudinal slit 360 is generally parallel with a plane defined by the upper edge 315 of the lower housing 303. Otherwise, the upper and lower housings 302, 303 may not sufficiently close the longitudinal slit 360 to create a proper seal. In one embodiment, the grommet 355 may include markings (not shown), such as embossed or printed words or symbols, to indicate the proper orientation of the grommet 355 and the longitudinal slit 360. In an alternate embodiment, the grommet 355 may include a helical slit (not shown) extending along the entire length of the grommet 355. In this embodiment, the grommet 355 may be wound around the fixture 304 prior to securing the upper and lower housings 302, 303. The helical slit is also configured to enable the grommet 355 to conform to a curved fixture 304.

Selecting a grommet 355 having the appropriate bore 356 inner diameter configures the lighting unit 300 to attach to a variety of different diameter fixtures 304. In one embodiment, the bore 365 inner diameter of the grommet 355 is substantially equal to an outer diameter of the fixture 304 to provide a seal between the grommet 355 and the fixture 304. In one embodiment, the inner diameter of the bore 356 may be between approximately 0.25″ and 2″, such as 0.5″, 0.75″, 1″, or 1.25″. It will be appreciated, however, that the inner diameter of the bore 356 in the grommet 355 is not limited to the values recited above, and any desired inner diameter may be selected based upon the size of the structure to which the lighting unit 300 will be secured. The grommet 355 may be comprised any suitably flexible and compressible material, such as silicone, rubber, or neoprene. In one embodiment, the grommet 355 may include pleats or bellows (i.e., an accordion-like structure) configured to allow the grommet 355 to rotate or bend to accommodate a curved fixture 304.

With reference now to FIGS. 9A-9C, the lighting unit 300 may include a support tray 365 configured to support various components housed in the interior cavity 305 of the housing 301. In the illustrated embodiment, the support tray 365 is configured to support one or more secondary (rechargeable) batteries 366 and two plug connectors (not shown). In one embodiment, the support tray 365 comprises an outer annular portion 370, a plurality of fastener receptacles 371 configured to align with the posts 351 in the lower housing 303, and channels 372 to support one or more secondary batteries 366. The annular ring 370 of the support tray 365 may be connected to the upper housing 302 by any suitable means, such as bonding, welding, or fastening. The fasteners 321 securing the support tray 365 and the upper housing 302 to the lower housing 303 are configured to extend through the fastener receptacles 371 in the support tray 365 and into the posts 351 in the lower housing 303. Additionally, a portion of the fastener receptacles 371 are configured to slide down over the annular groove (not shown) in the cylindrical posts 351 to ensure proper alignment between the fastener receptacles 371 and the cylindrical posts 351 prior to insertion of the fasteners 321. The support tray 365 may also include an opening configured to receive the plug connectors (not shown), described in more detail below. Although the support tray 365 has been described as a separate component, in one embodiment the support tray 365 may be integrally formed with either the upper housing 302 or the lower housing 303. In an alternate embodiment, the lighting unit 300 may be provided without a support tray 365, and the rechargeable battery 366 and the plug connectors (not shown) may be directly stored in the lower housing 303. Moreover, in one embodiment, the lighting unit 300 may be provided without plug connectors. In the embodiment in which the lighting unit 300 is provided without the support tray, the upper housing 302 may include fastener receptacles 367 configured to align with the posts 351 in the lower housing 303 and receive fasteners 321 securing the upper housing 302 to the lower housing 303, as illustrated in FIGS. 9A and 9B.

As illustrated in FIGS. 9A, 9B, and 10, the light collection assembly 306 is configured to be received in an upper opening 380 in the upper housing 302. The light collection assembly 306 comprises a photovoltaic cell 381, a lid 382, a printed circuit board (PCB) having a microcontroller thereon 383, and an upper cover 384. The photovoltaic cell 381 may be connected to the upper side of the PCB 383 or may be integrally formed with the lid 382. In one embodiment, the light collection assembly 306 may also include a lower cover (not shown). The photovoltaic cell 381 is configured to charge the secondary battery 366 and/or directly power the LED lights 327. The microcontroller 383 may be programmed to perform a variety of functions, such as reading the voltage across the photovoltaic cell 381, turning the LED lights 327 on at sunset and off at sunrise, changing the color of the light emitted from the LED lights 327, and recharging the battery 366. In one embodiment, the microcontroller 383 may be programmed with a summer mode and a winter mode. In the winter mode, the microcontroller 383 is programmed to reduce the intensity of the LED lights 327 (thereby conserving the charge of the battery 366), because the nights are longer during the winter months. In the summer mode, the microcontroller 383 is programmed to increase the intensity of the LED lights 327, because the nights are shorter during the summer months. The microcontroller 383 may also be configured to switch to a backup battery (not shown) if the main battery 366 is drained before sunrise. An axial opening 386 in the lid 382 is configured to receive the photovoltaic cell 381, the PCB 383, and the upper cover 384. The photovoltaic cell 381, the PCB 383, and the upper cover 384 may be connected to the lid 382 by any suitable means, such as bonding. The upper cover 384 is connected to an upper end of the opening 386 in the lid 382. In one embodiment, the lower cover is connected to a lower end of the opening 386 in the lid 382. The photovoltaic cell 381 and the PCB 383 are disposed between the upper cover 384 and lower cover (not shown), if provided, such that the upper and lower covers are configured to seal the photovoltaic cell 381 and the PCB 383 in the lid opening 386. Accordingly, the upper cover 384 and the lower cover, if provided, form a waterproof chamber in the lid 382 configured to house the photovoltaic cell 381 and the PCB 383. In the embodiment in which the lower cover is not provided, a bonding agent (e.g., epoxy) may be provided to seal the photovoltaic cell 381 and the PCB 383 into the opening 386 in the lid 382. In an alternate embodiment, the light collection assembly 306 may be provided without an upper cover, and the PCB 383 and the photovoltaic cell 381 may be bonded into the opening 386 in the lid 382 to form a watertight seal. The upper cover 384 is translucent or transparent to permit light to strike the surface of the photovoltaic cell 381. In one embodiment, the lower cover includes an opening, such as a circular through hole, through which the wires connecting the PCB 383 to the lighting assembly 307 pass. In one embodiment, the upper cover 384 is configured to be inserted down through the upper end of the opening 386 in the lid 382, and the photovoltaic cell 381 and the PCB 383 are configured to be inserted up through the lower end of the opening 386 in the lid 382.

Still referring to FIGS. 9A and 9B, the upper opening 380 in the upper housing 302 may include a channel or groove 388 extending around the periphery of the opening 380. The channel 388 is configured to receive an annular gasket 369, such as an o-ring. The annular gasket 369 is configured to prevent water propagating, such as by wicking, into the interior cavity 305 of the housing 301. The annular gasket 369 may be connected to the upper housing 302 by any suitable means, such as bonding.

With continued reference to FIGS. 9A and 9B, the lid 382 is removably connectable to the upper housing 302. The lid 382 includes an annular flange 390 configured to enable the user to remove the lid 382 to gain access to the various components in the interior cavity 305 of the housing 301 after the upper and lower housings 302, 303 are secured to the fixture 304. The annular flange 390 of the lid 382 is configured to overhang a portion of the upper housing 302 when the lid 382 is connected to the upper housing 302, as illustrated in FIG. 10. An upper surface of the flange 390 may include friction-inducing surface features 391, such as a knurled surface, ridges, or a coating configured to enable the user to twist the lid 382 between the engaged and disengaged positions without the user's fingers inadvertently slipping off the lid 382. The lid 382 may include a bayonet-style twist-and-lock connection to the upper housing 302. The bayonet-style connection is configured to prevent over-rotation of the lid 382 which could otherwise damage the wires connecting the photovoltaic cell 381 and the PCB 383 to the LED lights 327, the battery 366, and the switch 395.

The secondary battery 366 is configured to power the LED lights 327 in the lighting assembly 307. Although the lighting unit 300 has been described with reference to one secondary battery 366, the lighting unit 300 may be provided with any suitable number of batteries, for instance two, to achieve the desired capacity and/or voltage. In an embodiment in which more than one secondary battery 366 is provided, the secondary batteries may be wired together in either series or parallel depending upon the desired voltage of the batteries. The photovoltaic cell 381 is configured to recharge the secondary battery 366 and/or directly power the LED lights 327. The secondary battery 366 may be Alkaline, Nickel-Cadmium (NiCd), Nickel-metal hydride (NiMH), Lithium-ion, or any other type of secondary battery, depending upon the desired capacity and voltage of the battery. The rechargeable battery 366 may have a capacity between approximately 500 mA·h and 3000 mA·h. In an alternate embodiment, the lighting unit 300 may include a capacitor (not shown) configured to power the LED lights 327.

As described above with reference to FIG. 9C, in one embodiment the lighting unit 300 includes a support tray 365 configured to house upper and lower plug connectors (not shown). In one embodiment, the upper plug connector may be wired to the light collecting assembly 306, and the lower plug may be wired to the lighting assembly 307. The upper plug connector may be disconnected from the lower plug connector, such as when the upper housing 302 is to be separated from the lower housing 303 (i.e., the plug connectors are configured to provide an electrical disconnect). The upper plug may be reconnected to the lower plug before the upper housing 302 is reconnected to the lower housing 303. As described above, the lighting unit 300 may be provided without the upper and lower plug connectors. In an embodiment in which the lighting unit 300 is provided without upper and lower plug connectors, a sufficient length of wire connecting the photovoltaic cell 381 and the PCB 383 to the lighting unit 307 may be provided such that the upper housing 302 can be detached from the lower housing 303.

In one embodiment, the photovoltaic cell 381 can produce a maximum current of approximately 30 mA to charge the secondary battery 366 or directly power the LED lights 327. Although the photovoltaic cell 381 is shown having a square configuration, the photovoltaic cell 381 may have any other shape, such as round, and still fall within the scope and spirit of the present invention. In one embodiment, the photovoltaic cell 381 is substantially the same size and shape as the opening 386 in the lid 382. The photovoltaic cell 381 may also protrude from the outer surface of the upper housing 302. The photovoltaic cell 381 may comprise any suitable type of solar panel, such as monocrystalline silicon, polycrystalline silicon, or thin film (e.g., cadmium telluride, copper indium gallium selenide, or amorphous silicon). In an alternate embodiment, the secondary battery 366 may be charged via induction charging from an induction coil (not shown). In one embodiment, the induction coil may be integrated into the grommet 355. Moreover, the induction charger may be configured to collect electromagnetic energy running through the fixture 304 (e.g., a transmission line) extending through the grommet 355 in the housing.

In one embodiment, the microcontroller on the PCB 383 may be programmed to turn on the LED lights 327 when the photovoltaic cell 381 is producing current or voltage below a predetermined threshold, and to turn off the LED lights 327 when the photovoltaic cell 381 is producing current or voltage exceeding a predetermined threshold. In this manner, the microcontroller may be programmed such that the LED lights 327 are turned on when the photovoltaic cell 381 receives low light (e.g., dusk) and turned off when the photovoltaic cell 381 receives large amounts of light (e.g., sunrise). In an alternate embodiment, the light collecting assembly 306 may include a light sensor (not shown) electrically coupled to the LED lights 327, such that the lights 327 are turned on and off based on the level of ambient light sensed by the light sensor.

In the illustrated embodiment of FIG. 10, a lower end of the lower housing 303 contains an opening 392 configured to receive a switch 395, such as a push button switch. The switch 395 is electrically coupled to the microcontroller on the PCB 383. The switch 395 is configured to alternate between the various lighting modes programmed into the microcontroller. For instance, the switch 395 may be configured to turn on different color LED lights 327 (e.g., red, green, blue, or white), set a timer for the LED lights 327 (e.g., turn the lights on for 8 hours), and to turn the lights 327 on or off. Additionally, the opening 392 in the lower housing 303 may be configured to receive a depressible cover 396 connected to the switch 395. The depressible cover 396 is configured to seal the opening 392 in the lower housing 303 and thereby prevent water from propagating into the interior cavity 305 in the housing 301. In use, the user may depress the depressible cover 396 to actuate the switch 395. In an alternate embodiment, the lighting unit 300 may include a low power receiver or RFID reader (not shown) configured to receive a signal from a remote switch to actuate the LED lights 327.

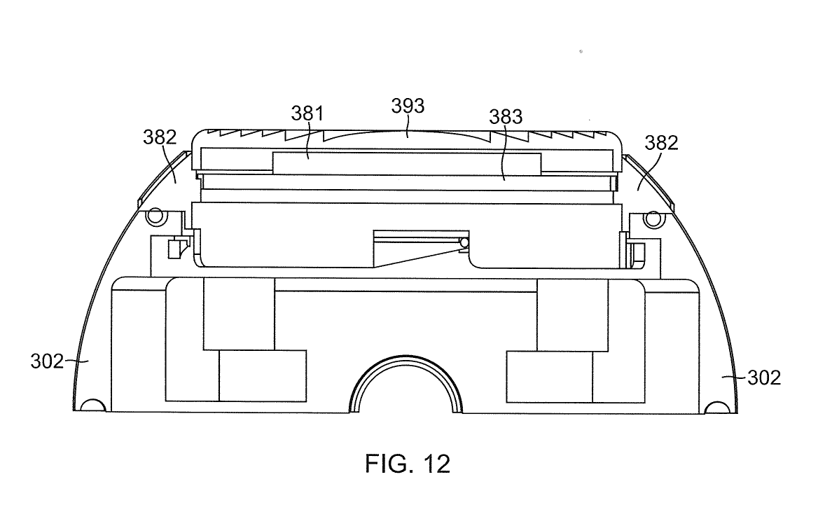

Referring now to the embodiment illustrated in FIG. 12, the light collection assembly 306 may include a lens 393, such as a Fresnel lens or any other converging lens, to direct sunlight toward the photovoltaic cell 381. The lens 393 may be configured to capture light striking the lighting unit 300 at an oblique angle (i.e., light which would otherwise strike the photovoltaic cell 381 at a shallow angle of incidence). For instance, the lens 393 may be configured to capture light when the sun is near the horizon, which would otherwise not be captured by the photovoltaic cell 381. The lens 393 may also be configured to concentrate the sunlight onto the photovoltaic cell 381. Accordingly, the lens 393 is configured to increase the electric output of the photovoltaic cell 381. The lens 393 may be provided instead of the upper cover 384 (see FIG. 9A), or may be provided in addition to the upper cover 384.

As shown in the figures, the lighting unit according to embodiments of the invention includes a smooth outer profile. For example, referring to FIG. 2, the lighting unit 10 includes an outer profile that is shaped by the smooth upper and lower housings 24, 26. The smooth outer shape of the housings is also configured to protect the user, such as when the user's hands contact the lighting unit installed on a hand railing. The solar panel module 50 fits into the top of the upper housing with a low profile, fitting smoothly into the recessed opening, and not creating any abrupt or large extensions. Likewise, the light source unit fits compactly into the lower housing (see FIG. 7B) without creating any sharp or abrupt extensions. As a result, the overall unit 10, 100, 200 is compact and streamlined. In FIG. 2, the unit 10 is shaped as a smooth sphere or ball. In other embodiments, the lighting unit 10 can be formed in other curved or ball shapes, such as a football-shape or an oval. The smooth, compact outer profile of the lighting unit reduces the risk that the lighting unit will interfere with other equipment on the boat, such as sails, ropes, and cables that may come into contact with unit 10, or become untied. In one embodiment, the lighting unit includes a housing with a smooth outer profile that is devoid of any sharp corners, projecting arms, or acute angles. Additionally, the mechanism for fastening the lighting unit to the tubular member is contained within the lighting unit, so that no separate external fastener extends from the lighting unit and risks tangling or impacting with lines, ropes, sails, or other operating parts of the ship.

In one embodiment, the lighting unit 10 is shaped as a smooth ball having a diameter between approximately 1 inch and 5 inches, such as 2.5 inches, 3 inches, or 3.5 inches. In one embodiment, the housing pieces 24, 26 are made of stainless steel, and in another embodiment, injection molded plastic, which may be coated with metal like stainless steel using an electroplating process such as vacuum metalizing. The housing pieces can also be provided in various colors, and can be printed with various designs. In one embodiment, the lighting unit is impact- and vibration-resistant so that it can continue operating in rough conditions.

A method of mounting a light source to a fixture on a boat is provided, according to one embodiment of the invention. In this method, optionally, as a first step, a pair of bushings may be attached to a rail or cable by placing first and second bushing pieces above and below the rail and then sliding the pieces together. Whether or nor the bushings are used, first and second housing modules are attached to the rail, optionally over the bushings, and attached to each other such as by screws or other mating connectors. A separate solar panel module may then be attached to the first housing module and plugged into a waterproof plug to electrically connect the solar panel. A separate light module may be attached to the first or second housing module, forming electrical contacts with the lighting unit. The lighting unit is self-contained and firmly secured to the rail, without the need to remove the rail or expose an open end of the rail.

According to various embodiments of the invention, a portable lighting unit may also be provided on other structures or vehicles, in addition to boats. For example, the lighting unit may be provided on balconies, porches, patios, outdoor stairways, and handrails on buildings and bridges, as well as on other vehicles such as trucks and recreational vehicles. In another embodiment, the lighting unit may be provided on power lines and transmission lines.

Although the present invention has been described and illustrated in respect to exemplary embodiments, it is to be understood that it is not to be so limited, since changes and modifications may be made therein which are within the full intended scope of this invention as hereinafter claimed.

What is claimed is:

1. A portable lighting unit attachable to a fixture, comprising:
a first housing comprising a first pair of opposing notches;
a second housing comprising a second pair of opposing notches, the first and second housings being attachable together with the notches cooperating to receive the fixture through the notches;
a photovoltaic cell mounted to one of the first and second housings;
a light source mounted to one of the first and second housings; and
at least one rechargeable battery housed within one of the first and second housings, the at least one rechargeable battery electrically coupled to the photovoltaic cell and to the light source.

2. The portable lighting unit of claim 1, further comprising a microcontroller electrically coupled to the photovoltaic cell and the light source.

3. The portable lighting unit of claim 1, wherein the microcontroller is configured to measure a voltage across the photovoltaic cell, and wherein the microcontroller is configured to turn off the light source if the voltage is above a predetermined threshold and to turn the light source on if the voltage is below a predetermined threshold.

4. The portable lighting unit of claim 1, further comprising a lid having a waterproof chamber configured to house the photovoltaic cell, wherein the lid is detachably connectable to one of the first and second housings to provide access to an interior cavity of the first and second housings.

5. The portable lighting unit of claim 4, wherein the lid includes a bayonet-style connector for detachably connecting the lid to one of the first and second housings.

6. The portable lighting unit of claim 1, wherein the photovoltaic cell comprises a solar panel selected from the group consisting of monocrystalline silicon, polycrystalline silicon, and thin film devices.

7. The portable lighting unit of claim 1, further comprising a casing having a waterproof cavity configured to house the light source, wherein the casing is rotatably receivable in an opening in one of the upper and lower housings.

8. The portable lighting unit of claim 7, wherein the casing is rotatably mounted to one of the first and second housings by a gimbal.

9. The portable lighting unit of claim 7, wherein the casing is configured to rotate approximately 90 degrees in a first direction and approximately 45 degrees in a second direction, the second direction perpendicular to the first direction.

10. The portable lighting unit of claim 7, further comprising an annular gasket configured to encircle a portion of the casing.

11. The portable lighting unit of claim 10, further comprising a pressure plug configured to compress the annular gasket between the lower housing and the casing.

12. The portable lighting unit of claim 1, further comprising a grommet having an axial length removably receivable within the first and second pairs of notches, the grommet having an opening configured to receive a portion of the fixture.

13. The portable lighting unit of claim 12, wherein an inner diameter of the opening in the grommet is substantially equal to an outer diameter of the fixture.

14. The portable lighting unit of claim 12, wherein the grommet is rotatable within the first and second pairs of notches to accommodate a curved fixture.

15. The portable lighting unit of claim 12, wherein the grommet further comprises a narrow longitudinal slit extending along the axial length, wherein the first and second housings are configured to close the slit.

16. The portable lighting unit of claim 12, wherein the grommet further comprises a narrow helical slit extending along the axial length.

17. The portable lighting unit of claim 12, wherein the grommet further comprises first and second opposite bulbous ends, wherein the first and second pairs of notches are configured to compress the bulbous ends, and wherein the bulbous ends are configured to rotate in the first and second pairs of notches to accommodate a curved fixture.

18. The portable lighting unit of claim 1, further comprising a light sensor electrically coupled to the light source, the light sensor configured to actuate the light source.

19. The portable lighting unit of claim 1, further comprising a switch electrically coupled to the light source, wherein the switch may be selectively operated for actuating the light source.

20. The portable lighting unit of claim 1, further comprising a lens configured to direct light to an exterior surface of the photovoltaic cell.

21. The portable lighting unit of claim 20, wherein the lens is a magnifying lens.

22. The portable lighting unit of claim 20, wherein the lens is a Fresnel lens.

23. The portable lighting unit of claim 1, wherein the light source comprises at least one light emitting diode (LED).

24. The portable lighting unit of claim 1, wherein the light source comprises at least one red light emitting diode (LED) configured to aid a user's vision at night.

25. The portable lighting unit of claim 1, wherein the first and second housings comprise a substantially smooth outer profile.

26. A portable lighting system, comprising:
a lighting unit comprising:
a housing having first and second opposing housing portions;
first and second opposing openings in the housing;
a light source mounted to one of the first and second housing portions; and
a solar panel electrically coupled to the light source and mounted to the other housing portion; and
a grommet removably receivable within the first and second openings, wherein the grommet comprises a longitudinal opening configured to receive a fixture, and wherein the grommet is rotatable within the first and second openings.

27. A method for installing and operating a lighting unit, comprising:
attaching first and second housings to each other around a fixture, the first and second housings having opposing first and second openings configured to receive the fixture;
attaching a solar panel to the first housing;
attaching a light source to one of the first and second housings; and
electrically coupling the solar panel to the light source.

28. The method of claim 27, further comprising:
providing a grommet having a longitudinal opening with an inner diameter substantially equal to an outer diameter of the fixture; and
passing the fixture through the longitudinal opening in the grommet, wherein attaching the first and second housings to each other comprises attaching the housings around the grommet.

29. The method of claim 27, further comprising rotating the light source with respect to the second housing module into a desired orientation.

30. The method of claim 27, further comprising attaching a pressure plug to one of the first and second housings, the pressure plug creating a seal between the light source and one of the first and second housings.

31. The method of claim 27, further comprising coupling a microcontroller to the solar panel and the light source, the microcontroller programmed with a plurality of lighting modes.

32. The method of claim 31, further comprising coupling a switch to one of the first and second housings, wherein the switch is configured to electronically communicate with the microcontroller.

33. The method of claim 32, further comprising activating the switch to select a desired one of the plurality of lighting modes.

34. The method of claim 33, wherein activating the switch sets the light source to illuminate for a predetermined period of time.

35. The method of claim 33, wherein activating the switch sets the light source to illuminate during low ambient light.

36. The method of claim 33, wherein activating the switch turns on the light source.

37. The method of claim 33, wherein activating the switch turns off the light source.

38. The method of claim 33, wherein activating the switch sets the color of the light emitted from the light source.

39. The method of claim 27, further comprising remotely operating the light source.

40. The method of claim 27, further comprising coupling a light sensor to the light source.
